(19) United States
(12) Patent Application Publication
(10) Pub. No.: US 2012/0320286 A1
(43) Pub. Date: Dec. 20, 2012

(54) TELEVISION RECEIVER AND ELECTRONIC DEVICE

(75) Inventors: Chiari Shimizu, Tokyo (JP); Makoto Tanaka, Tokyo (JP); Mitsuhiro Murakami, Tokyo (JP); Daisuke Maehara, Tokyo (JP)

(73) Assignee: KABUSHIKI KAISHA TOSHIBA, Tokyo (JP)

(21) Appl. No.: 13/436,773

(22) Filed: Mar. 30, 2012

(30) Foreign Application Priority Data
Jun. 17, 2011 (JP) 2011-135159

(51) Int. Cl. H04N 5/64; H05K 7/00

(52) U.S. Cl. 348/836; 361/752; 348/E05.128

(57) ABSTRACT

According to one embodiment, a television receiver includes: a housing; a display device; a first board; a second board; a first card module; and a second card module. The second board includes a first surface and a second surface. The first surface includes a first connector, a first fixing portion, and a first planer portion with no surface mount component. The second surface includes a second connector, a second fixing portion, and a second planer portion with no surface mount component. The first card module is provided on the first planer portion and along the first surface. The second card module is provided on the second planer portion and along the second surface at a position at least partially overlapping the first card module in a thickness direction of the second board, and has higher operation temperature than the first card module.

### CROSS-REFERENCE TO RELATED APPLICATIONS

This application is based upon and claims the benefit of priority from Japanese Patent Application No. 2011-135159, filed Jun. 17, 2011, the entire contents of which are incorporated herein by reference.

### FIELD

Embodiments described herein relate generally to a television receiver and an electronic device.

### BACKGROUND

Conventionally, electronic devices that contain a module provided to a board in a housing are known.

In such an electronic device, if a plurality of modules are provided to the board, for example, a size of the housing is likely to be large.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary front view of a television receiver according to a first embodiment;

FIG. 2 is an exemplary side view of the television receiver in the first embodiment;

FIG. 3 is an exemplary perspective view of an assembly of a board and modules contained in a housing of the television receiver in the first embodiment;

FIG. 4 is an exemplary side view of the assembly illustrated in FIG. 3 in the first embodiment;

FIG. 5 is an exemplary plan view of the assembly illustrated in FIG. 3 on a first surface side in the first embodiment;

FIG. 6 is an exemplary plan view of the assembly illustrated in FIG. 3 on a second surface side in the first embodiment;

FIG. 7 is an exemplary perspective view of the board illustrated in FIG. 3 in the first embodiment;

FIG. 8 is an exemplary side view of the board illustrated in FIG. 7 in the first embodiment;

FIG. 9 is an exemplary plan view of a first surface of the board illustrated in FIG. 7 in the first embodiment;

FIG. 10 is an exemplary plan view of a second surface of the board illustrated in FIG. 7 in the first embodiment;

FIG. 11 is an exemplary side view of a modification of the assembly of the board and the modules contained in the housing of the television receiver in the first embodiment;

FIG. 12 is an exemplary sectional view (side view) of apart of the board illustrated in FIG. 11 in the first embodiment;

FIG. 13 is an exemplary sectional view of the housing of the television receiver in which the board illustrated in FIG. 12 is housed in the first embodiment;

FIG. 14 is an exemplary sectional view of a housing of a television receiver whose specifications are different from those of the television receiver illustrated in FIG. 13, and in which the board illustrated in FIG. 12 is housed, in the first embodiment;

FIG. 15 is an exemplary perspective view of an electronic device according to a second embodiment;

FIG. 16 is an exemplary front view of the electronic device in the second embodiment;

FIG. 17 is an exemplary back view of the electronic device in the second embodiment;

FIG. 18 is an exemplary side view of the electronic device in the second embodiment;

FIG. 19 is an exemplary side view of the electronic device viewed from a different direction from the direction in FIG. 18, in the second embodiment;

FIG. 20 is an exemplary side view of the electronic device viewed from another different direction from the directions in FIGS. 18 and 19, in the second embodiment;

FIG. 21 is an exemplary side view of the electronic device viewed from still another different direction from the directions in FIGS. 18 to 20, in the second embodiment;

FIG. 22 is an exemplary exploded perspective view of the electronic device in the second embodiment;

FIG. 23 is an exemplary plane view of an internal configuration of the electronic device in the second embodiment;

FIG. 24 is an exemplary sectional view taken along line XXIV-XXIV in FIG. 16 in the second embodiment;

FIG. 25 is an exemplary perspective view of a part of the internal configuration of the electronic device in the second embodiment;

FIG. 26 is an exemplary perspective view of another part of the internal configuration of the electronic device in the second embodiment;

FIG. 27 is an exemplary plane view of the part illustrated in FIG. 26 in the second embodiment;

FIG. 28 is an exemplary perspective view of the part illustrated in FIG. 26 viewed from a different angle, in the second embodiment; and

FIG. 29 is an exemplary perspective view of a part of the electronic device in the second embodiment.

### DETAILED DESCRIPTION

In general, according to one embodiment, a television receiver comprises: a housing; a display device; a first board; a second board; a first card module; and a second card module. The housing comprises an opening. The display device is housed in the housing and comprises a display screen visible through the opening. The first board is housed in the housing and comprises a heating element mounted thereon. The second board is housed in the housing at a position different from that of the first board, has a size different from that of the first board, is configured to be electrically connected to the first board, and comprises a first surface and a second surface. The first surface is positioned on the display device side and the second surface is positioned on a side opposite the first surface. The first surface comprises a first connector, a first fixing portion, and a first planer portion positioned between the first connector and the first fixing portion with no surface mount component mounted thereon. The second surface comprises a second connector, a second fixing portion, and a second planer portion positioned between the second connector and the second fixing portion with no surface mount component mounted thereon. The first card module is configured to be electrically connected to the first connector, and provided on the first planer portion and along the first surface. The second card module is provided on the second planer portion and along the second surface at a position at least partially overlapping the first card module in a thickness direction of the second board, is electrically connected to the second connector, and has higher operation temperature than the first card module.

Exemplary embodiments described below comprise components similar to each other. Therefore, in the description below, common numerals are assigned to similar components, and explanation thereof will be omitted. Furthermore, in the drawings, directions (X direction, Y direction, and Z direction) are illustrated for convenience. The X direction is a longitudinal direction with respect to a display screen 4a viewed from the front, the Y direction is a lateral direction with respect to the display screen 4a viewed from the front, and the Z direction is a front-back direction (depth direction or thickness direction of a housing 3) with respect to the display screen 4a viewed from the front. The X direction, the Y direction, and the Z direction are orthogonal to one another.

In the embodiments below, an electronic device is embodied as a television receiver or a personal computer. However, the electronic device according to the present embodiment is not limiter thereto, and can be embodied as various types of electronic devices, such as a smartphone, a smartbook, a mobile phone, a personal digital assistant (PDA), an image display, and a video phone.

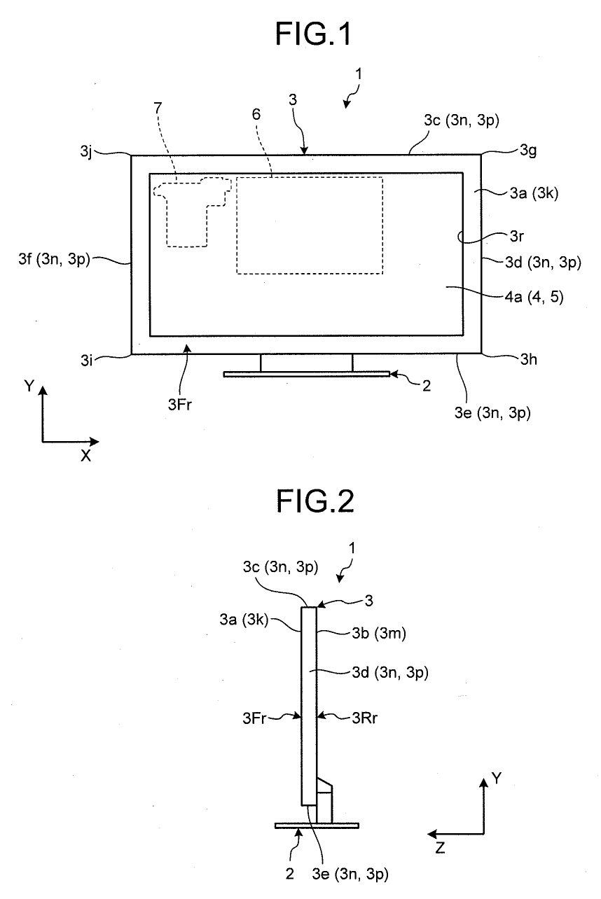

A television receiver 1, which is an example of the electronic device according to the present embodiment, comprises a support (a support portion, a base, or a stand) 2 and the housing 3 as illustrated in FIGS. 1 and 2. The support is placed on a mounting (not illustrated), such as a desk, a shelf, and a cabinet, and supports the housing 3. The support may support the housing 3 fixedly, or support the housing 3 in a movable (rotatable or slidable) manner. Aspects of the housing 3 being rotatable with respect to the support include a tilt, a swivel, and a pivot.

As illustrated in FIG. 1, the housing 3 is configured in a rectangular shape (an oblong shape in the present embodiment, for example) viewed from the front. Furthermore, as illustrated in FIG. 2, the housing 3 is configured in a flat rectangular parallelepiped shape that has small width in the front-back direction. The housing 3 comprises a front surface (a front face, a surface, a first surface, or a first surface portion) 3a, and a rear surface (a back surface, a surface, a second surface, or a second surface portion) 3b opposite thereto. The front surface 3a and the rear surface 3b are approximately parallel to each other. Furthermore, as illustrated in FIG. 1, the housing 3 comprises four ends (sides or edges) 3c to 3f and four corners (peaks, curves, or ends) 3g to 3j viewed from the front. The ends 3c and 3e are examples of a long side, and the ends 3d and 3f are examples of a short side.

The housing 3 further comprises a wall (a first wall, a first portion, a plate, a frame, a front wall, a face wall, or a top wall) 3k comprising the front surface 3a and a wall (a second wall, a second portion, a plate, a rear wall, a back wall, or a bottom wall) 3m comprising the rear surface 3b. The walls 3k and 3m are in a rectangular shape (an oblong shape in the present embodiment, for example). Furthermore, the housing 3 comprises four walls (third walls, third portions, plates, side walls, end walls, standing walls, or extending portions) 3n comprising a side surface (a surface, a surrounding surface, or a third surface) 3p extending between the wall 3k and the wall 3m. The wall 3k has an opening 3r in a rectangular shape, for example.

Furthermore, the housing 3 can be configured by combining a plurality of components (divided parts or members). The housing 3, for example, comprises a first member (a first portion, a front side member, or a cover) 3Fr containing at least the wall 3k and a second member (a second portion, a rear side member, a base, or a bottom) 3Rr containing at least the wall 3m. The wall 3n can be contained in at least one of the first member 3Fr and the second member 3Rr (e.g., the second member 3Rr). The housing 3 can comprise a third member (a third portion, a middle member, a dividing member, a barrier member, a wall member, an intervening member, an inner plate, a middle plate, or a middle frame, which is not illustrated) arranged between the first member 3Fr and the second member 3Rr in addition to the first member 3Fr and the second member 3Rr. In this case, the wall 3n can be contained in the third member. The housing 3 can be made of a metal material, a synthetic resin material, and the like.

The housing 3 houses a display device (a display module, a display, or a panel) 4. The display screen 4a arranged on the front surface 3a side of the display device 4 is exposed forward (outside) of the housing 3 through the opening 3r. A user can visually confirm the display screen 4a from the front side through the opening 3r. The display device 4 is configured in a rectangular shape (an oblong shape in the present embodiment, for example) viewed from the front. Furthermore, the display device 4 is configured in a flat rectangular parallelepiped shape that has small width in the front-back direction. The display device 4 is, for example, a liquid crystal display (LCD) and an organic electro-luminescent display (GELD).

The front side (face side or wall 3k side) of the display device 4 is provided with a transparent input operation panel (e.g., a touch panel, a touch sensor, and an operation surface) 5 in a relatively thin rectangular shape. The input operation panel 5 covers the display screen 4a. An operator (user or the like) uses a finger or a stylus, for example, to perform an operation such as touching, pressing, sliding, and moving in the vicinity of the input operation panel 5 with respect to the input operation panel 5, thereby performing input processing. Furthermore, light output from the display screen 4a of the display device 4 passes through the input operation panel 5, and is output forward (outside) of the housing 3 through the opening 3r of the wall 3k. The input operation panel 5 is an example of an input module.

The housing 3 houses a plurality of boards 6 and 7 on the rear side (back side, other side, wall 3m side, side opposite to the display screen 4a) of the display device 4. The boards 6 and 7 are arranged in different positions, and are provided in a manner parallel to the display device 4. Furthermore, the boards 6 and 7 are provided in a manner separated from the walls 3k, 3m, 3n, and the like, that is, with spacing between the boards 6 and 7 and the walls 3k, 3m, 3n, and the like. It is preferable that the boards 6 and 7 be arranged side by side along the display device 4, and not be overlapping each other in the depth direction of the housing 3. The boards 6 and 7 are fixed to the housing 3 by a fixture such as a screw.

A plurality of electronic components (components or elements, which are not illustrated) such as a central processing unit (CPU) are mounted on the board (first board, first circuit board, control board, or main board) 6 illustrated in FIG. 1. The electronic components comprise a heating element. An electronic component (heating element) that has a large amount of heat generation can be provided with a cooling mechanism (a heat releasing module or a heat receiving module, which is not illustrated). The board 6 and the electronic components constitute at least apart of a control circuit (not illustrated). The control circuit can comprise an image signal processing circuit, a tuner, a high-definition multimedia interface (HDMI) signal processor, an audio video (AV) input terminal, a remote-control signal receiver, a controller, a selector, an on-screen display interface, a storage (e.g., a read-only memory (ROM), a random access memory (RAM), and a hard disk drive (HDD)), and a voice signal processing circuit, for example. The control circuit controls output of an image (a moving image, a still image, or the like) by the display screen 4a of the display device 4, output of sound by a speaker (not illustrated), emission of light by a light emitting diode (LED, which is not illustrated), and the like. The display device 4, the speaker, the LED, and the like are examples of an output module.

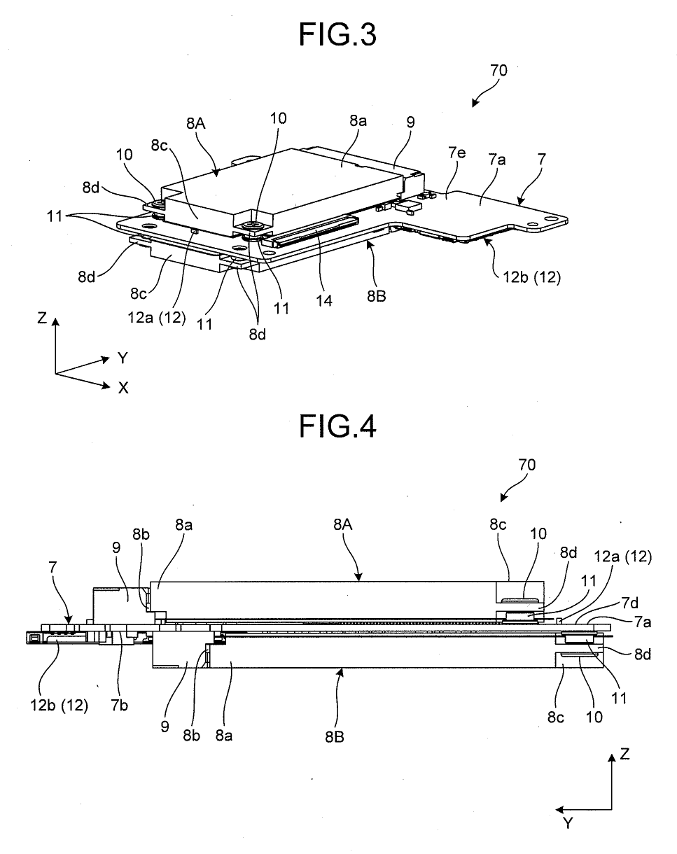

The board (second board, second circuit board, module board, or sub board) 7 illustrated in FIGS. 3 to 10 comprises a plurality (two in the present embodiment) of modules (card modules, components, electronic components, storage devices, antennas, or elements) 8A and 8B. The board 7 is electrically connected to the board 6 via a flexible cable (not illustrated) or the like. The board 7 may comprise various types of modules 8A and 8B, such as a solid state drive (SSD) module and a wireless communication module. In the present embodiment, a configuration in which the board 7 comprises two of the modules 8A and 8B is exemplified. Alternatively, the board 7 may comprise three or more modules. Furthermore, while two of the modules 8A and 8B are in a nearly same shape in the present embodiment, for example, two of the modules 8A and 8B may be different in shape. The module 8A is an example of a first card module, and the module 8B is an example of a second card module. The number of electronic components mounted on the board 7 is smaller than the number of electronic components mounted on the board 6. The size of the board 7 is smaller than that of the board 6. Furthermore, the number of cables connecting the board 7 and other components in the housing 3 is smaller than the number of cables connecting the board 6 and other components in the housing 3. In other words, the board 7 has higher portability than the board 6. Furthermore, in terms of order of working process, the board 7 can be incorporated in the housing 3 after relatively large components including the board 6 are mounted therein.

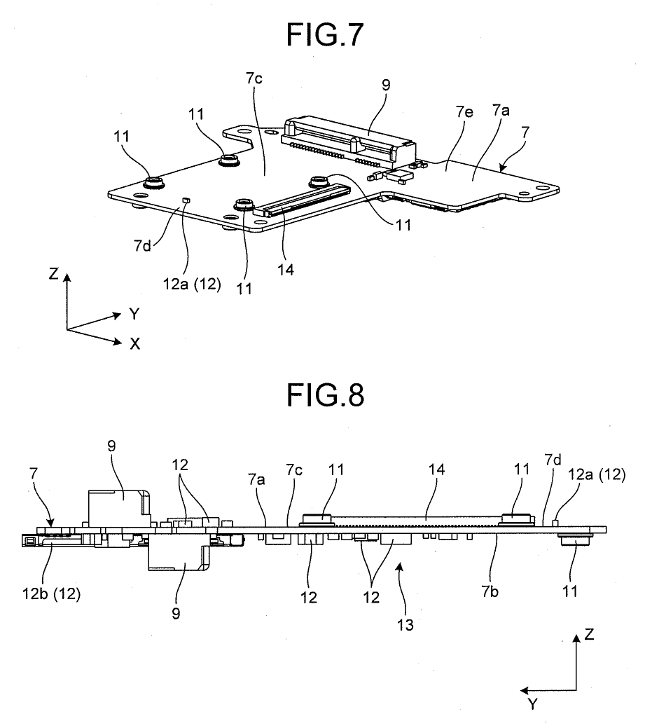

FIGS. 3 to 6 illustrates the board 7 on which the modules 8A and 8B are mounted, and FIGS. 7 to 10 illustrates the board 7 from which the modules 8A and 8B are removed (are not mounted). In the present embodiment, for example, the module 8A is provided to a first surface (a first face, a first portion, or a first area) 7a of the board 7, whereas the module 8B is provided to a second surface (a second face, a second portion, or a second area) 7b of the board 7. In the present embodiment, for example, the first surface 7a and the module 8A are arranged on the front side (display device 4 side, face side, or first side), whereas the second surface 7b and the module 8B are arranged on the rear side (opposite side of the display device 4 side, back side, or second side).

As illustrated in FIGS. 3 to 6, both of the modules 8A and 8B are formed in a flat rectangular parallelepiped shape, and have an appearance of a rectangular shape (oblong shape) in the planer view. A connector module 8b is provided to an end (a side or an edge) 8a corresponding to a short side on one side in the longitudinal direction of the modules 8A and 8B. The connector module 8b comprises a plurality of terminals (not illustrated). The terminals are aligned along the end 8a. The board 7 comprises a connector 9. The connector module 8b is inserted into the connector 9, and is electrically connected to the connector 9. In other words, the terminals of the connector module 8b and terminals (not illustrated) of the connector 9 come into contact with each other in a conductive state. The connector 9 is an example of a first connector or a second connector.

By contrast, a fixing portion (a supporting portion or a retaining portion) 8d is provided to an end (a side, or an edge) 8c corresponding to a short side on the other side in the longitudinal direction serving as the side opposite to the end 8a. In the present embodiment, for example, the fixing portion 8d is arranged at a corner (a peak, a curve, or an end) of the modules 8A and 8B. In the present embodiment, for example, a recessed portion (an opening or a notch) in a rectangular shape viewed from the front is provided to the front side and the rear side of the corner, and the fixing portion 8d is formed in a plate shape and a flange shape. The fixing portion 8d has an opening (e.g., a through hole and a notch, which is not illustrated) through which a screw 10 serving as a fixture (an inserted member, a fixing member, or a positioning member) passes. The screw 10 that passes through the opening is fixed to a female screw (a stud or a boss) 11 provided to the board 7. The female screw 11 is an example of a first fixing portion or a second fixing portion. The fixture is not limited to the screw, and may be a clip, a pin, and a rivet, for example. Furthermore, the fixture can be fixed to at least one of the modules 8A and 8B and the board 7.

As illustrated in FIGS. 7 to 10, the connector 9 and the female screws 11 corresponding to the module 8A are provided to the first surface 7a of the board 7. By contrast, the connector 9 and the female screws 11 corresponding to the module 8B are provided to the second surface 7b. Furthermore, a planer portion (an area, a module, or a surface portion) 7c is provided to an area surrounding the connector 9 and the female screws 11 on the first surface 7a and the second surface 7b. In the present embodiment, for example, no surface mount component (electronic component or component) is mounted on the planer portion 7c. However, it is just an example, and a component at least a part of which protrudes from the surface of the board 7, a component a part of which is embedded in the board 7, and the like can be mounted on the planer portion 7c. Furthermore, the planer portion 7c is an area in which no component is provided or an area in which the protruding height of a component is lower at a position corresponding to (facing) the modules 8A and 8B on the first surface 7a or the second surface 7b of the board 7. The planer portion 7c is provided so as to prevent the height of an assembly 70 from being made high by laminating the modules 8A and 8B and the component in the thickness direction of the board 7. In other words, a component with a height (a mounted height or a protruding height) that does not interfere with the modules 8A and 8B can be provided to the planer portion 7c.

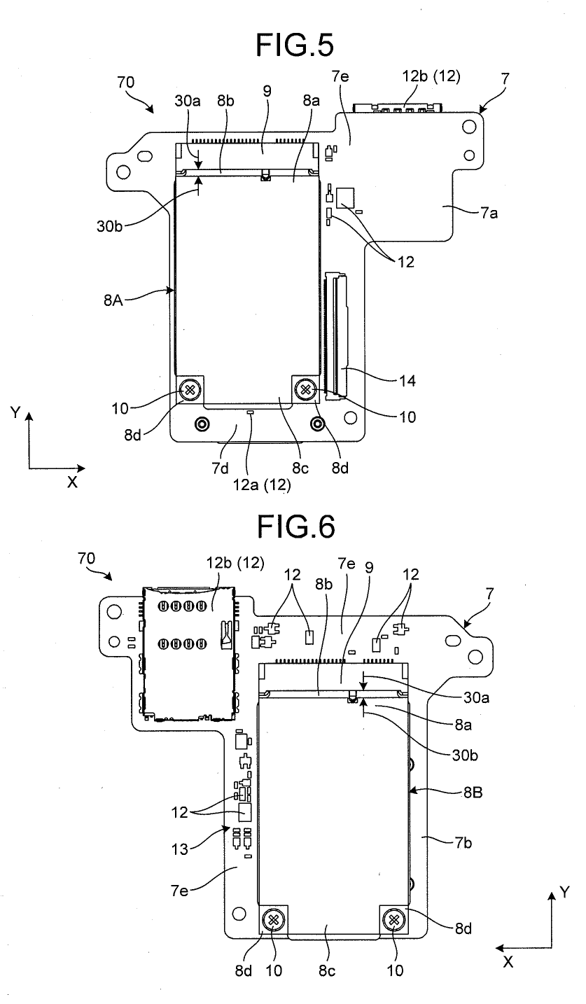

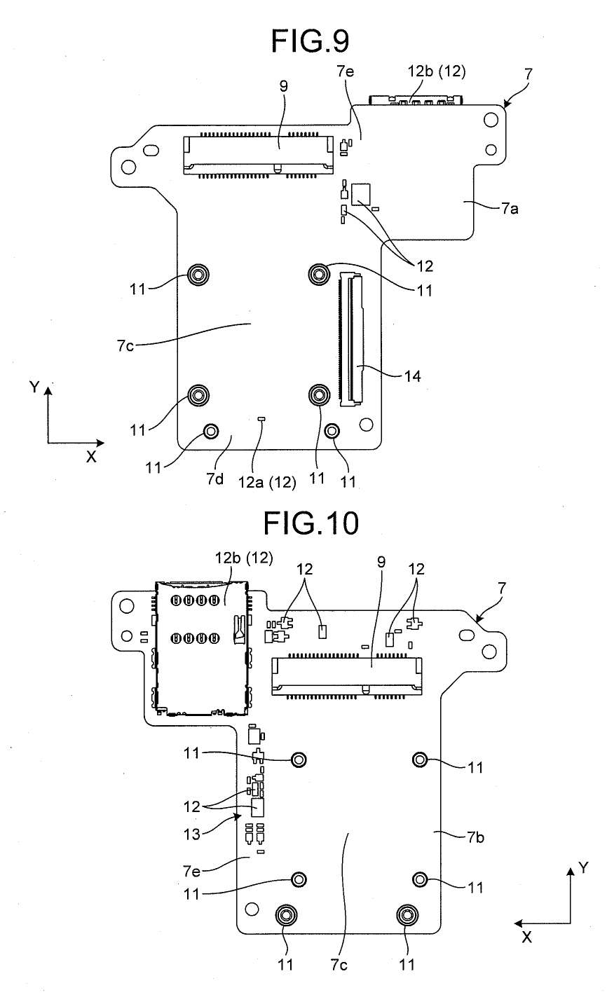

By comparing FIG. 5 with FIG. 9 and FIG. 6 with FIG. 10 for reference, it is found that the modules 8A and 8B are arranged on the planer portion 7c (placed on top of the planer portion 7c) in the present embodiment, for example. As illustrated in FIG. 4, the modules 8A and 8B are arranged along the first surface 7a or the second surface 7b in the present embodiment, for example. In other words, in the present embodiment, such a configuration can make the assembly (second assembly) 70 of the board 7 and the modules 8A and 8B thinner. The planer portion 7c is an example of a first planer portion or a second planer portion. In the present embodiment, the female screws 11 that are distant from the connector 9 and the female screws 11 that are closer to the connector 9 are provided. With this configuration, it is possible to provide another module (not illustrated) that is different in size (length in the vertical direction in FIGS. 5 and 9) from the modules 8A and 8B to the board 7.

In the present embodiment, as illustrated in FIGS. 4, 5, and or other figures, an electronic component 12 is provided by surface mounting, for example, to an area (a back side area or a third planer portion) 7d that is an area other than the planer portion 7c of the first surface 7a and the second surface 7b, and that is positioned on the back sides of the modules 8A and 8B. In the present embodiment, a temperature sensor (e.g., thermistor) 12a is provided to the area 7d of the first surface 7a as an example of the electronic component 12. As illustrated in FIG. 4, the temperature sensor 12a is arranged on the backside of the module 8B provided to the second surface 7b in the present embodiment, for example. Such a layout of the module 8B and the temperature sensor 12a is obtained due to the arrangement in which the modules 8A and 8B overlaps each other not completely but partially in the thickness direction of the board 7. In other words, the modules 8A and 8B are misaligned with respect to each other along the first surface 7a or the second surface 7b of the board 7. As a result, the area 7d on which the electronic component 12 can be mounted is provided to the back sides of the modules 8A or 8B on the first surface 7a or the second surface 7b (the first surface 7a in the present embodiment, for example). Such a layout, for example, allows the electronic component 12 to be arranged on the back sides of the modules 8A and 8B with the board 7 interposed therebetween. Thus, for example, the electronic component 12 can be arranged closer to the modules 8A and 8B. Therefore, for example, it is possible to detect or estimate the temperature and the amount of heat generation of the module 8B more accurately by using the temperature sensor 12a. If the modules 8A and 8B are misaligned with each other in the longitudinal direction (direction along the long side of the rectangle), the area 7d is likely to be made smaller compared to the case where the modules 8A and 8B are misaligned with each other in the lateral direction (direction along the short side of the rectangle). Therefore, for example, the assembly 70 is unlikely to be made large in the direction along the first surface 7a and the second surface 7b of the board 7. Note that the temperature sensor 12a is just an example, and an electronic component 12 other than the temperature sensor 12a can be provided to the back sides of the modules 8A and 8B. The electronic component 12 can be provided to the second surface 7b on the back side of the module 8A. The area 7d is an example of the first area and the second area.

In the present embodiment, the electronic components 12 are arranged along the edge of the board 7 and in the periphery of the planer portion 7c so as to avoid the planer portion 7c. Such a configuration, for example, allows a worker to confirm the planer portion 7c visually, and to confirm the positions of the modules 8A and 8B in a simple manner by the electronic components 12 when mounting the modules 8A and 8B.

In the present embodiment, the electronic component 12 is also provided by surface mounting, for example, to an area (a peripheral area or a fourth planer portion) 7e that is an area other than the planer portion 7c of the first surface 7a and the second surface 7b, and that is not positioned on the back sides of the modules 8A and 8B, that is, to the area 7e other than the planer portion 7c and the area 7d. In the present embodiment, as illustrated in FIGS. 6 and 10, a circuit 13 containing the electronic component 12 is provided to the area 7e. Furthermore, in the present embodiment, the module 8B provided to the second surface 7b is a module for a third generation mobile communication system (3G), for example. A card holder 12b for an identification (ID) card (a subscriber identity module (SIM) card) used in the 3 G communications is provided to the second surface 7b next to the module 8B. The card holder 12b is an example of the electronic component 12.

A connector 14 for the flexible cable (not illustrated) electrically connecting the board 6 and the board 7 is provided to the first surface 7a of the board 7.

In the present embodiment, as illustrated in FIGS. 5 and 6, indexes 30a and 30b for mounting are provided to the modules 8A and 8B, and the connector 9. In the present embodiment, for example, the indexes 30a and 30b are provided to the connector 9 and the modules 8A and 8B as a symbol (mark) of an arrow. The indexes 30a and 30b are provided by printing or pasting stickers, for example. If a combination of the module 8A and the connector 9 is correct, the index 30a and the index 30b are aligned with each other. By contrast, if a combination of the module 8A and the connector 9 is wrong, the index 30a and the index 30b do not align with respect to each other. In the present embodiment, for example, the positions of the index 30b of the module 8A and the index 30a of the connector 9 corresponding thereto and the positions of the index 30b of the module 8B and the index 30a of the connector 9 corresponding thereto are misaligned with respect to each other in the direction along the connector 9 (direction along the end 8a, direction of the short side, or direction along the terminals of the connector module 8b and the connector 9). Therefore, the indexes 30a and 30b allow the worker to confirm visually or tactually whether the modules 8A and 8B are combined with the connector 9 properly. Presence of visual correspondence therebetween can be confirmed by the positions of the indexes 30a and 30b, and colors thereof, for example. Such a configuration, for example, can prevent the modules 8A and 8B from being mounted in the connector 9 erroneously. The indexes 30a and 30b are not limited to this example, and can be changed in various ways. The indexes 30a and 30b may be, for example, characters, patterns, pictures, colors, figures, shapes (e.g., protruding portions or recessed portions). Furthermore, the index may be provided to one of the modules 8A and 8B and the connector 9, and may be provided to one of the modules 8A and 8B. Moreover, the index may be provided to the board 7 (e.g., the first surface 7a and the second surface 7b), the screw 10, the female screw 11, and the like.

In the present embodiment, the television receiver 1 comprises the board 7 in which the module 8A is provided to the first surface 7a, and the module 8B is provided to the second surface 7b in addition to the board 6. Therefore, for example, the flexibility of the layout of the components in the housing 3 can be enhanced, thereby preventing the size of the housing 3 to become large. Furthermore, for example, compared with the case where the modules 8A and 8B are provided side by side to one surface of the board 6 or the board 7, it is possible to prevent the size of the housing 3 to become large in the direction along the surface of the board 6 or the board 7. Moreover, the modules 8A and 8B are provided not to the board 6 but to the board 7. As a result, for example, the flexibility in the process of mounting the modules 8A and 8B and in the process of mounting components corresponding to the modules 8A and 8B can be enhanced compared with the case where the modules 8A and 8B are provided to the board 6. Note that the components corresponding to the modules 8A and 8B include a terminal or a connector used for electrically connecting the modules 8A and 8B to other components or boards, more specifically, a terminal of an antenna cable. Accordingly, it is possible to reduce work and costs of manufacturing.

In the present embodiment, the module 8B that has higher operation temperature than the module 8A is arranged on the side closer to the wall 3m of the housing 3, whereas the module 8A that has lower operation temperature than the module 8B is arranged on the display device 4 side. Therefore, for example, heat generated by the module 8B can be easily released outside the housing 3 through the wall 3m. Furthermore, for example, it is possible to reduce effects of the heat generated by the module 8B on the display device 4.

In the present embodiment, the electronic component 12 is provided to the area 7d positioned on the back sides of the modules 8A and 8B on the first surface 7a or the second surface 7b of the board 7. Therefore, for example, the electronic component 12 can be positioned closer to the modules 8A and 8B. If the electronic component 12 is the temperature sensor 12a, for example, the temperature sensor 12a can detect the temperatures of the modules 8A and 8B more accurately.

In the present embodiment, the modules 8A and 8B are misaligned along in the longitudinal direction thereof. Therefore, for example, the size of the area 7d positioned on the back sides of the modules 8A and 8B on the first surface 7a and the second surface 7b of the board 7 by misaligning the modules 8A and 8B can be made small compared with the case where the modules 8A and 8B are misaligned with each other along the lateral direction thereof.

In the present embodiment, card-type modules are exemplified as the modules 8A and 8B. However this is just an example, and the modules 8A and 8B are only needed to have a structure in which an area (surface) facing the board 7 is a plane surface (a flat surface, an approximately flat surface, or a surface along the board 7), and with which the modules 8A and 8B can be connected to the connector 9 in a manner at least partially overlapping each other with the board 7 interposed therebetween. Thus, the modules 8A and 8B are not limited to the card-type modules.

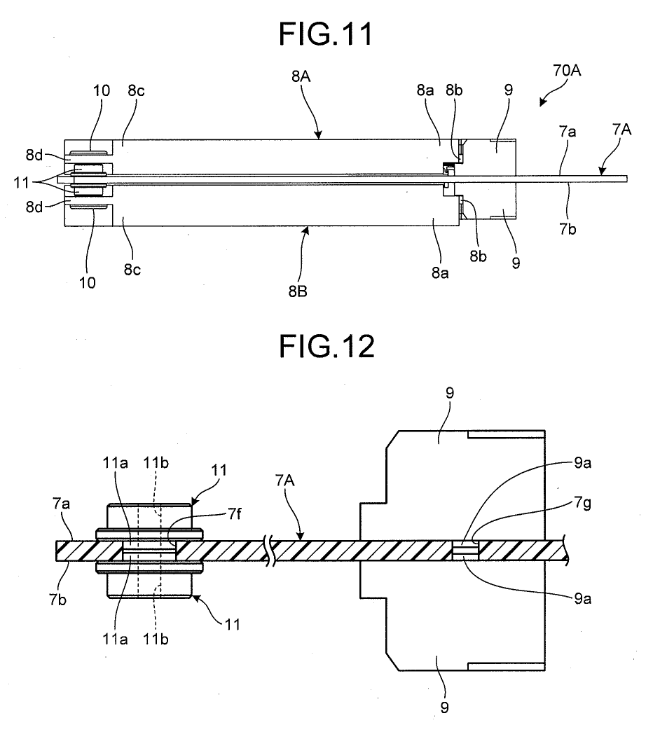

FIGS. 11 and 12 illustrates a board (second board) 7A and an assembly 70A according to a modification. The board 7A and the assembly 70A can be substituted for the board 7 and the assembly 70 of the first embodiment. In the present modification, for example, the modules 8A and 8B are in a nearly same shape (a rectangular shape or an oblong shape) in a planer view with respect to the first surface 7a and the second surface 7b of the board 7A (viewed from a direction perpendicular to the first surface 7a and the second surface 7b or from the thickness direction of the board 7A (vertical direction in FIGS. 11 and 12)). Accordingly, for example, the specs (sizes and shapes) for the connector 9 and the female screw 11 used for the modules 8A and 8B can be the same, thereby reducing work and costs of manufacturing.

In the present modification, for example, the modules 8A and 8B completely overlaps each other in the thickness direction of the board 7A. Therefore, for example, it is possible to prevent the board 7A from being made large in the direction along the first surface 7a and the second surface 7b. Accordingly, for example, it is possible to prevent the housing 3 and thus the size of the television receiver (electronic device) 1 to become large.

Furthermore, in the present modification, as illustrated in FIG. 12, the board 7A comprises through holes 7f and 7g. A projection 11a of the female screw 11 provided to the first surface 7a and the projection 11a of the female screw 11 provided to the second surface 7b are inserted into the through hole 7f. In other words, the through hole 7f functions as a positioning portion for these two female screws 11, and is shared by the female screws 11 to fix (position) the two female screws 11 to the board 7A. The female screw 11 comprises a female screw hole 11b. A male screw (not illustrated) of the screw 10 serving as a fixture is connected to the female screw hole 11b. Furthermore, for example, the female screw 11 is fixed to the board 7A by being soldered, for example, to a pad (not illustrated) made of copper foil and the like provided to the first surface 7a and the second surface 7b of the board 7A. The configuration of the female screw 11 being fixed to the board 7A may be employed in the first embodiment as well.

A projection 9a of the connector 9 provided to the first surface 7a and the projection 9a of the connector 9 provided to the second surface 7b are inserted into the through hole 7g. In other words, the through hole 7g functions as a positioning portion for these two connectors 9, and is shared by the two connectors 9 to fix (position) the connectors 9 to the board 7A. The connector 9 is fixed to the board 7A by being soldered, for example, to a pad (not illustrated) made of copper foil and the like provided to the first surface 7a and the second surface 7b of the board 7A, for example. The configuration of the connector 9 being fixed to the board 7A may be employed in the first embodiment as well. The through hole 7g is an example of a second through hole.

As described above, in the present modification, the through holes 7f and 7g are shared by the components (electronic components, connector 9, female screw 11, and the like) provided to the first surface 7a and the components (electronic components, connector 9, female screw 11, and the like) provided to the second surface 7b. Accordingly, for example, it is possible to reduce work and costs of manufacturing.

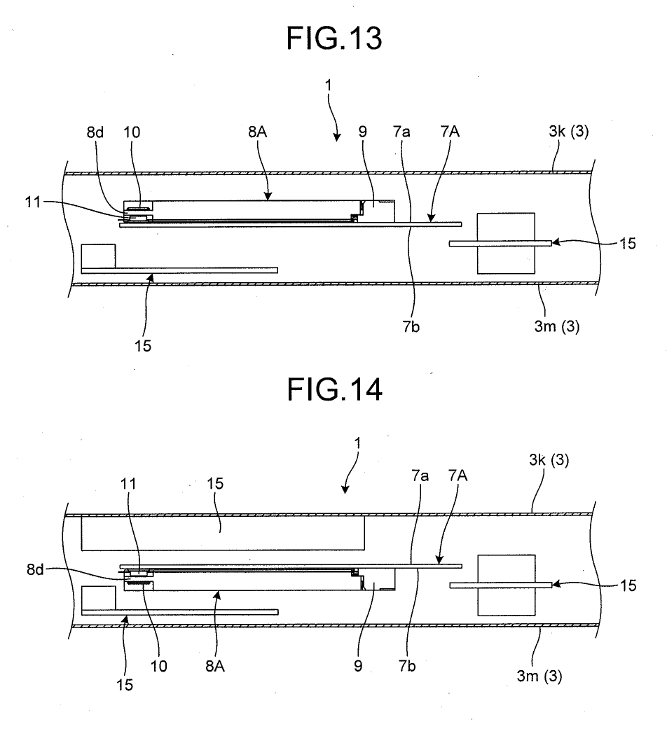

The configuration of the through holes 7f and 7g being shared in the present modification has an advantage in that, as illustrated in FIGS. 13 and 14, for example, the board 7A can be shared by a plurality of television receivers (electronic devices) 1 that have different layouts of components 15 in the housing 3. Specifically, for example, in the specification illustrated in FIG. 13, the module 8A is provided to the first surface 7a of the board 7A. By contrast, in the specification illustrated in FIG. 14, another component (e.g., a card holder) 15 is provided on the first surface 7a side in the housing 3. If the module 8A is provided to the first surface 7a, the module 8A interferes with the component 15. Therefore, in the specification illustrated in FIG. 14, the module 8A that performs the same function as that in the case of FIG. 13 is provided to the second surface 7b of the board 7A. Thus, with the board 7A according to the present modification, for example, the board 7A can be shared by a plurality of specifications of the television receiver (electronic device) 1. Accordingly, for example, it is possible to reduce work and costs of manufacturing compared with the case where the board 7A is manufactured for each of the specifications.

An electronic device 1B according to the present embodiment is, for example, a personal computer, a television receiver, a smartphone, a smartbook, a mobile phone, and a PDA of a so-called slate-type and a tablet-type comprising a display device having a function of a soft keyboard.

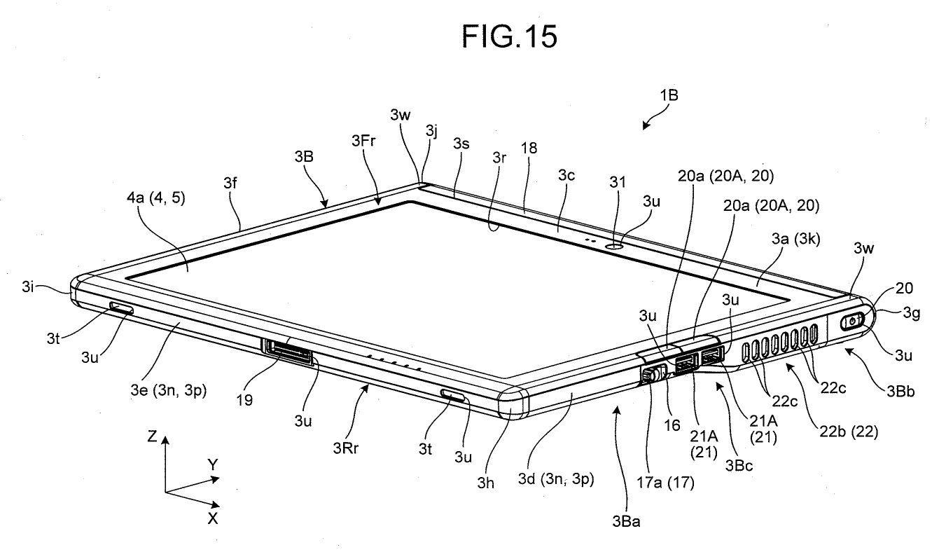

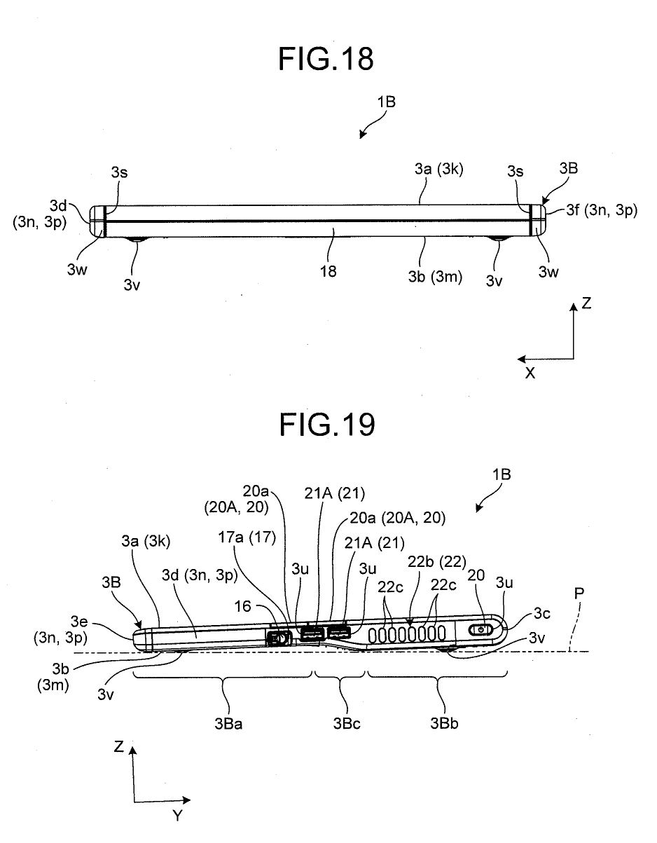

As illustrated in FIGS. 15 to 17, a housing 3B of the electronic device 1B is configured in a rectangular shape (an oblong shape in the present embodiment, for example) viewed from the front and the back. Furthermore, as illustrated in FIGS. 18 to 21, the housing 3B is configured in a flat rectangular parallelepiped shape that has small width in the front-back direction. The housing 3B comprises a front surface (a front face, a surface, a first surface, or a first surface portion) 3a, and a rear surface (a back surface, a surface, a second surface, or a second surface portion) 3b opposite thereto. The front surface 3a and the rear surface 3b are approximately parallel to each other. Furthermore, as illustrated in FIGS. 15 to 17, the housing 3B comprises four ends (sides or edges) 3c to 3f and four corners (peaks, curves, or ends) 3g to 3j viewed from the front. The ends 3c and 3e are examples of a long side, and the ends 3d and 3f are examples of a short side.

The housing 3B further comprises a wall (a first wall, a first portion, a plate, a frame, a front wall, a face wall, or a top wall) 3k comprising the front surface 3a and a wall (a second wall, a second portion, a plate, a rear wall, a back wall, or a bottom wall) 3m comprising the rear surface 3b. The walls 3k and 3m are in a rectangular shape (an oblong shape in the present embodiment, for example). Furthermore, the housing 3B comprises four walls (third walls, third portions, plates, side walls, end walls, standing walls, or extending portions) 3n comprising a side surface (a surface, a surrounding surface, or a third surface) 3p extending between the wall 3k and the wall 3m. The wall 3k has an opening 3r in a rectangular shape, for example.

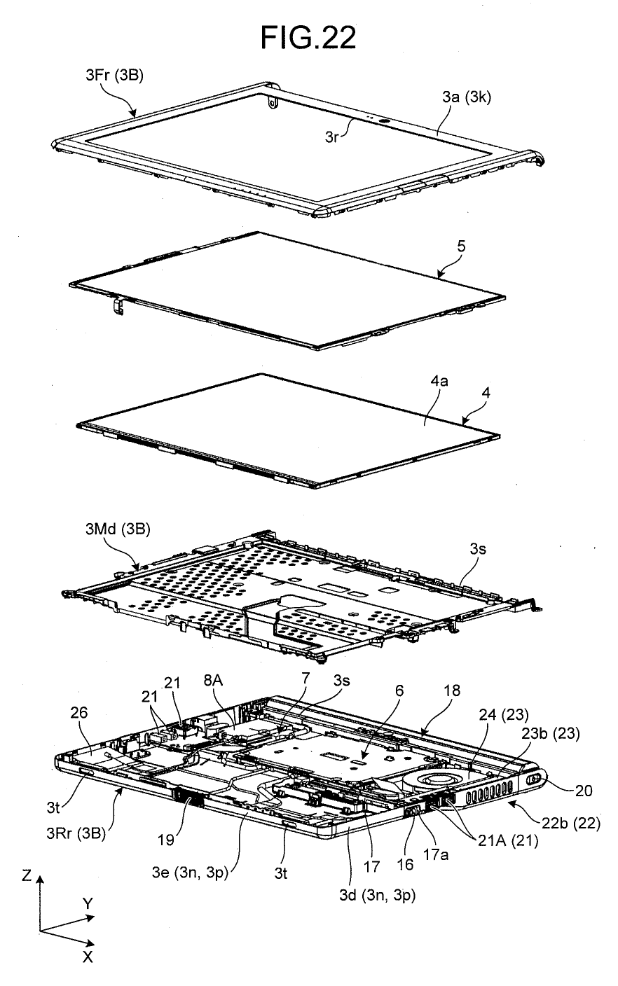

Furthermore, the housing 3B can be configured by combining a plurality of components (divided parts). The housing 3B, for example, comprises a first member (a first portion, a front side member, or a cover) 3Fr containing at least the wall 3k and a second member (a second portion, a rear side member, a base, or a bottom) 3Rr containing at least the wall 3m. The wall 3n is contained in at least one of the first member 3Fr and the second member 3Rr (e.g., the second member 3Rr). In the present embodiment, as illustrated in FIG. 22, the housing 3B further comprises a third member 3Md (a third portion, a middle member, a dividing member, a barrier member, a wall member, an intervening member, an inner plate, a middle plate, or a middle frame) arranged between the first member 3Fr and the second member 3Rr in addition to the first member 3Fr and the second member 3Rr. A part of the wall 3n can be contained in the third member 3Md. The housing 3B can be made of a metal material, a synthetic resin material, and the like. The second member 3Rr and the third member 3Md can be made of a metal material such as magnesium alloy, for example. The first member 3Fr can be made of a synthetic resin material that has lower stiffness than that of the second member 3Rr and the third member 3Md. A wall (a projection or a protruding wall) such as a rib can be provided to the first member 3Fr, the second member 3Rr, and the third member 3Md. The wall increases the stiffness of the housing 3B. Furthermore, the third member 3Md can comprise an opening such as a through hole. The opening can make the housing 3B lighter.

In the present embodiment, as illustrated in FIGS. 19 and 21, for example, the thickness of a first portion 3Ba on the lower side or the near side (side closer to the user) when the electronic device 1B is used with the longitudinal direction thereof placed horizontally is smaller than that of a second portion 3Bb on the upper side or the far side (side distant from the user) in the same used state. Therefore, if the electronic device 1B is used while being placed on amounting surface P such as a desk, the height of the front surface 3a of the housing 3B and the display screen 4a from the mounting surface P increases from the near side (lower side) to the far side (upper side). Therefore, according to the present embodiment, for example, the display screen 4a is in a so-called tilted state with respect to the user positioned on the left side of the electronic device 1B in FIG. 19 or on the right side of the electronic device 1B in FIG. 21. As a result, the user can see the display screen 4a more easily.

The direction of an image output on the display screen 4a while the electronic device 1B is being used can be changed depending on the position of the housing 3B (electronic device 1B). A control circuit (not illustrated) provided in the housing 3B, for example, can change the direction and the size of an image output on the display screen 4a in accordance with a detection result of a sensor (e.g., a gyro sensor and an acceleration sensor) provided in the housing 3B. Furthermore, the control circuit can restrict the position of the image to some positions. Specifically, for example, when the end 3c of the housing 3B is positioned above the end 3e (a first position), the control circuit can display an image whose top is on the end 3c side on the display screen 4a. By contrast, when the end 3d is positioned above the end 3f (a second position), the control circuit can display an image whose top is on the end 3d side on the display screen 4a. If the position of the housing 3B is changed from a previous position to the first position or the second position, the control circuit changes the image on the display screen 4a to an image corresponding to the position. By contrast, if the position is changed from the previous position to a position other than the first position or the second position (that is, in this example, a position in which the end 3e is positioned above the end 3c or a position in which the end 3f is positioned above the end 3d), the control circuit does not change the image on the display screen 4a. Such control can restrict the position of the electronic device 1B being used by the user.

The housing 3B comprises a component housing module 17 that houses a component 16 in a removable manner. An opening 17a of the component housing module 17 is bored in the end 3d in the present embodiment, for example. The opening 17a is provided to the end 3d that is located on the upper side in any of the used positions (the first position or the second position in the example described above), and that is not located on the lower side in a non-used position. Such a configuration causes the opening 17a to be located on the upper side in the used position. Therefore, for example, it is possible to prevent the component 16 from falling off the component housing module 17 by the action of gravity. Specifically, the component 16 is a stylus, a stylus pen, and a pen, for example.

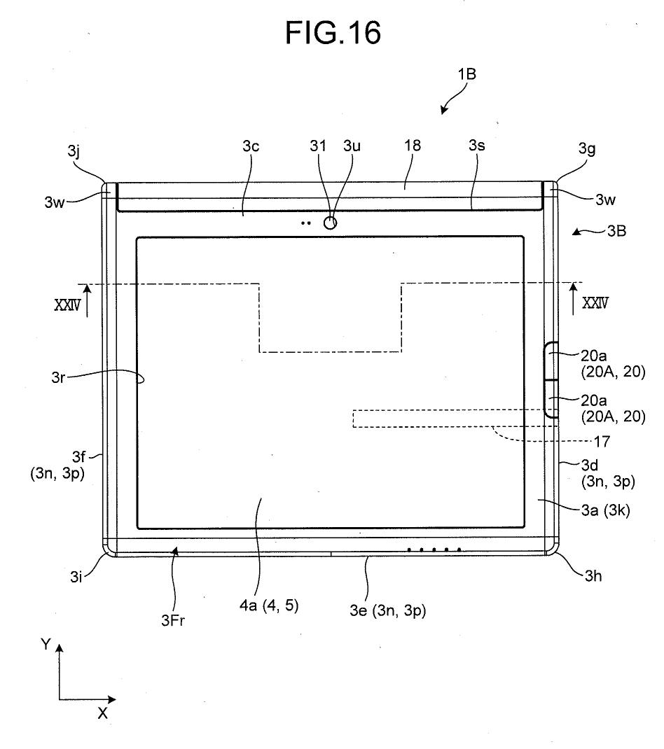

As illustrated in FIG. 16, in the present embodiment, a battery 18 and the display device 4 are arranged side by side in a direction perpendicular to the thickness direction of the housing 3B without overlapping with each other in the thickness direction. The direction perpendicular to the thickness direction of the housing 3B is a direction along the front surface 3a or the rear surface 3b, or the X direction or the Y direction, and is the Y direction in the present embodiment, for example. Therefore, it is possible to make the housing 3B thin compared with the case where the battery 18 and the display device 4 are overlapped with each other in the thickness direction of the housing 3B. Furthermore, compared with the case where the battery 18 and the display device 4 are overlapped with each other in the thickness direction of the housing 3B, for example, it is possible to make the battery 18 thick. As a result, the capacity of the battery 18 per unit volume can be increased. Furthermore, as illustrated in FIGS. 19 and 21, the housing 3B comprises the thinner first portion 3Ba and the thicker second portion 3Bb in the present embodiment. A battery housing module (battery supporting module) 3s that houses the battery 18 is provided to the end 3c of the thicker second portion 3Bb. Therefore, compared with the case where the battery housing module 3s is provided to the first portion 3Ba, for example, it is possible to make the battery 18 thick. As a result, the capacity of the battery 18 per unit volume can be increased.

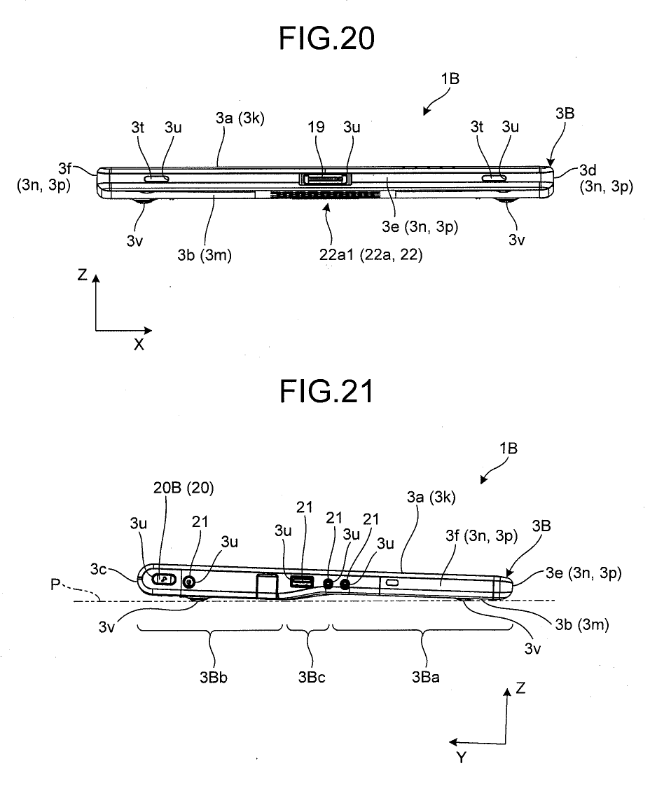

In the present embodiment, the end 3e on the opposite side of the end 3c to which the battery housing module 3s is provided is supported by a docking station (another electronic device, which is not illustrated). Therefore, for example, the worker (user) can attach and detach the battery 18 to and from the housing 3B with the electronic device 1B being supported by the docking station. Furthermore, as illustrated in FIGS. 15 and 20, a connector 19 connected to a connector (not illustrated) of the docking station is provided to the end 3e. Therefore, for example, the battery housing module 3s and the connector 19 can be provided to the housing 3B without interfering with each other. A terminal 3t is also exposed on the end 3e. The connector 19 and the terminal 3t are exposed through openings 3u provided to the wall 3n on the end 3e.

In the battery housing module 3s, a coupling of two or more (two or three) of the first member 3Fr, the second member 3Rr, and the third member 3Md of the housing 3B is provided to a part hidden by the battery 18. In this coupling, for example, the first member 3Fr and the third member 3Md or the second member 3Rr are coupled with each other by a screw as an example of a coupling tool. When disassembling the housing 3B, the worker (user or the like) removes the screw first, and separates the first member 3Fr and the third member 3Md or the second member 3Rr at least locally at this module to be taken apart. Subsequently, while deforming the first member 3Fr elastically by applying a force to the separated module, for example, the worker releases coupling of an elastic coupling (engaging portion or connecting portion; e.g., an engaging portion with a catch and an edge of a hole (not illustrated)) of the first member 3Fr and the third member 3Md or the second member 3Rr. Thus, the worker removes the first member 3Fr from the third member 3Md or the second member 3Rr. A plurality of couplings (engaging portions or connecting portions) of the first member 3Fr and the third member 3Md or the second member 3Rr are arranged along the perimeter of the first member 3Fr. All of a plurality of screws (not illustrated) serving as coupling tools for coupling the second member 3Rr and the third member 3Md are covered by the first member 3Fr. Therefore, by removing the first member 3Fr from the third member 3Md or the second member 3Rr, the worker can remove the screws, and separate the second member 3Rr and the third member 3Md. With such a configuration, when the battery 18 is removed from the battery housing module 3s, it is possible to disassemble the housing 3B smoothly. In other words, it is possible to prevent the housing 3B from being disassembled with the battery 18 mounted in the battery housing module 3s.

Furthermore, in the present embodiment, the second member 3Rr and the third member 3Md extend to the battery housing module 3s, and constitute a part of the end 3c (wall 3n or side surface 3p). Therefore, for example, the stiffness of the housing 3B can be increased. Furthermore, because the stiffness of the battery housing module 3s is increased, it is possible to suppress vibrations and misalignment of the battery 18 more reliably, for example.

As illustrated in FIGS. 15 to 21, an operation module 20 and connectors 21 are provided to the front surface 3a and the side surface 3p of the housing 3B. The operation module 20 can be a push button, a push switch, a slide switch, and a pointing device, for example. The connector 21 is a connector for a power cable, a universal serial bus (USB) connector, a connector for earphones and a microphone, or the like. The operation module 20 and the connectors 21 are exposed through the openings 3u provided to the walls 3k and 3n of the housing 3B. Furthermore, a camera (a camera module or an imaging device) 31 can be provided to the front surface 3a.

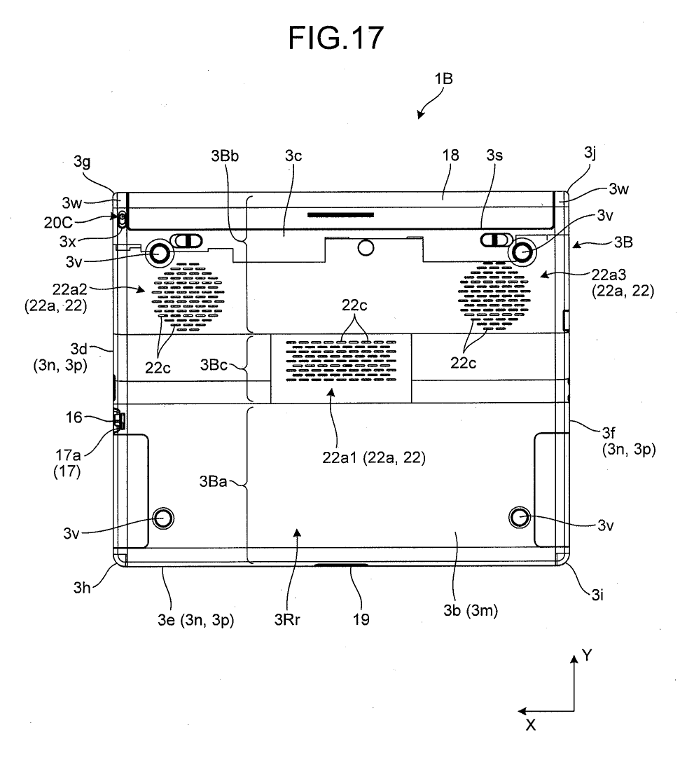

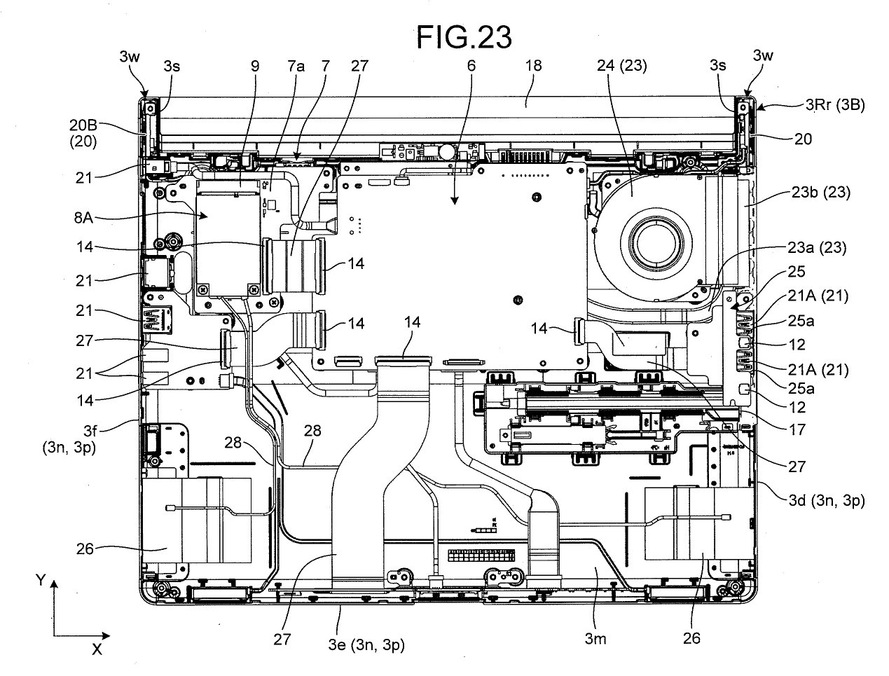

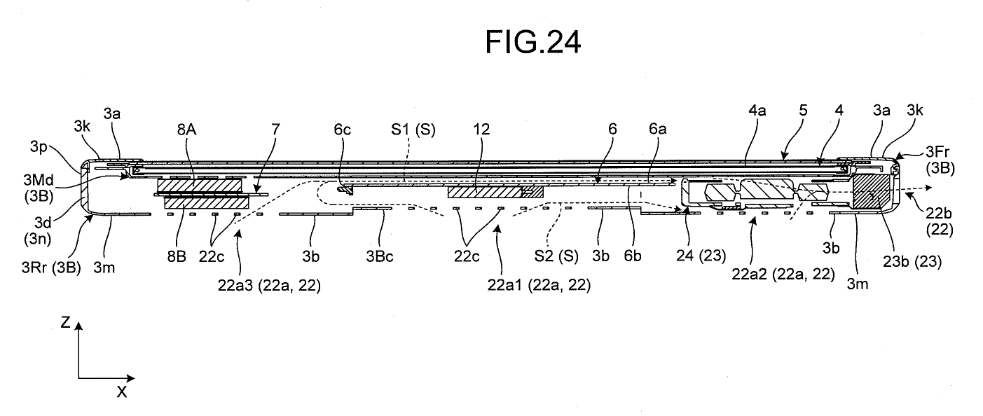

As illustrated in FIGS. 17 and 19, vents 22 that let the air used for cooling the electronic component 12 (refer to FIG. 24 and other figures) and for other use in and out are provided to the rear surface 3b and the side surface 3p of the housing 3B. In the present embodiment, for example, inlets 22a to which the air is introduced are provided to the rear surface 3b (wall 3m), and an outlet 22b from which the air is emitted is provided to the side surface 3p (wall 3n or end 3d). In the present embodiment, the inlet 22a and the outlet 22b are provided as a portion in which a plurality of pores 22c are collected on the walls 3m and 3n. Projections 3v are provided to the rear surface 3b. Therefore, if the rear surface 3b is placed on the mounting surface P as illustrated in FIGS. 19 and 21, the inlets 22a are not blocked. Furthermore, in the present embodiment, an inclined portion 3Bc is provided to the boundary of the thinner first portion 3Ba and the thicker second portion 3Bb of the housing 3B. As illustrated in FIG. 17, an inlet 22a1 of the inlets 22a is provided to the rear surface 3b of the inclined portion 3Bc. As illustrated in FIGS. 19 and 21, the distance between the inclined portion 3Bc and the mounting surface P is larger than those between other portions and the mounting surface P. As a result, in the inlet 22a1 provided to the inclined portion 3Bc, resistance of air flow can be reduced, whereby it is possible to improve the cooling efficiency. Furthermore, the inlet 22a is provided in plurality in the present embodiment. Therefore, even if one of the inlets 22a is blocked for any cause, for example, airflow can be introduced into the housing 3B from other inlets 22a. As a result the cooling performance is unlikely to deteriorate. Note that the inside of the housing 3B may be cooled by a cooling mechanism 23 (refer to FIG. 23), or may be cooled by natural cooling (convection cooling).

As illustrated in FIG. 22, for example, the display device (display module, display, or panel) 4 is housed between the first member 3Fr and the third member 3Md in the housing 3B in the present embodiment as well. The display screen 4a of the display device 4 arranged on the front surface 3a side is exposed forward (outside) of the housing 3B through the opening 3r. The user can visually confirm the display screen 4a from the front side through the opening 3r. The display device 4 is configured in a rectangular shape (an oblong shape in the present embodiment, for example) viewed from the front. Furthermore, the display device 4 is configured in a flat rectangular parallelepiped shape that has small width in the front-back direction. The display device 4 is, for example, an LCD and an GELD.

The front side (face side or wall 3k side) of the display device 4 is provided with the transparent input operation panel (e.g., a touch panel, a touch sensor, and an operation surface) 5 in a relatively thin rectangular shape. The input operation panel 5 covers the display screen 4a. The operator (user or the like) uses a finger or the component 16 (stylus), for example, to perform an operation such as a touch, a press, a slide, and a motion in the vicinity of the input operation panel 5 with respect to the input operation panel 5, thereby performing input processing. Furthermore, light output from the display screen 4a of the display device 4 passes through the input operation panel 5, and is output forward (outside) of the housing 3 through the opening 3r of the wall 3k. The input operation panel 5 is an example of the input module.

As illustrated in FIGS. 22, 23, and other figures, the housing 3B houses a plurality of boards 6, 7 and 25 on the rear side (back side, other side, wall 3m side, side opposite to the display screen 4a side) of the display device 4, that is, between the second member 3Rr and the third member 3Md in the present embodiment, for example. The boards 6, 7, and 25 are arranged in different positions, and are provided in a manner parallel to the display device 4. Furthermore, the boards 6, 7 and 25 are provided in a manner separated from the walls 3k, 3m, 3n, and the like, that is, with space interposed between the boards 6, 7 and 25 and the walls 3k, 3m, 3n, and the like. It is preferable that the boards 6, 7, and 25 be arranged side by side along the display device 4, and be not overlapped with one another in the depth direction of the housing 3B. The boards 6, 7 and 25 are fixed to the housing 3B by a fixture such as a screw.

A plurality of electronic components 12 (refer to FIG. 24 and other figures, a part of which alone is illustrated in FIG. 24) can be mounted on the board (first board, first circuit board, control board, or main board) 6. The electronic components 12 include a CPU, a graphic controller, a power circuit component, a platform controller hub (PCH), a memory slot connector, an LCD connector, an input/output (I/O) connector, a power coil, an element, and a connector. The electronic components 12 include a heating element. The electronic component (heating element) 12 that has a large amount of heat generation can be provided with the cooling mechanism 23. The cooling mechanism 23 comprises a heat sink (a heat receiving module, which is not illustrated), a heat pipe 23a, a heat releasing module 23b, a fan 24, and the like. The board 6 and the electronic components 12 constitute at least a part of a control circuit (not illustrated). The control circuit comprises an image signal processing circuit, a tuner, an HDMI signal processor, an AV input terminal, a remote-control signal receiver, a controller, a selector, an on-screen display interface, a storage (e.g., a ROM, a RAM, and an HDD), and a voice signal processing circuit, for example. The control circuit controls output of an image (a moving image, a still image, or the like) by the display screen 4a of the display device 4, output of sound by a speaker (not illustrated), emission of light by an LED (not illustrated), and the like. The display device 4, the speaker, the LED, and the like are examples of the output module.

The board 7 and the modules 8A and 8B have the same configuration as that in the first embodiment. In the present embodiment as well, the first surface 7a of the board 7 and the module 8A are positioned on the display device 4 side, whereas the second surface 7b and the module 8B are positioned on the side opposite to the display device 4 side. Furthermore, the first surface 7a, the second surface 7b, and the modules 8A and 8B are arranged along the display device 4. The board 25 comprises the electronic components 12. The housing 3B houses flexible cables 27. The flexible cables 27 electrically connect the boards 6, 7, and 25, the display device 4, the connector 19, and the like. The flexible cable 27 is electrically connected to the connector 14 corresponding thereto. The flexible cable 27 is a flexible printed wiring board, and a flat cable, for example.

As illustrated in FIG. 23, the housing 3B houses a plurality of antennas 26. In the present embodiment, the antennas 26 connected to one communication module (e.g., the module 8B) are arranged in a manner separated from each other. In the present embodiment, for example, one of the antennas 26 is arranged near the end 3d and the end 3e (near the corner 3h) of the housing 3B, whereas the other of the antennas 26 is arranged near the end 3e and the end 3f (near the corner 3i) of the housing 3B. With this configuration, for example, it is possible to achieve space diversity of the antennas 26. The antenna 26 and the module 8B are electrically connected via a cable 28. Functions can be divided between the antennas 26 and 26 such that one of the antennas 26 is used for transmitting and receiving, and the other of the antennas 26 is used for receiving only. Alternatively, one of the antennas 26 can be used as a spare of the other of the antennas 26.

As is clear from FIGS. 17 and 23, the boards 6 and 7 and the cooling mechanism 23 are arranged in the thicker second portion 3Bb of the housing 3B. Therefore, for example, compared with the case where the boards 6 and 7 and the cooling mechanism 23 are arranged in the thin first portion 3Ba, the space can be secured more widely. As a result, a cooling effect of the air flow generated by the fan 24 of the cooling mechanism 23 can be obtained more reliably. Furthermore, in the present embodiment, the fan 24 and the heat releasing module 23b are provided to the corner 3g to which the end 3c and the end 3d, which are located on the upper side in the specified (controlled) used state, are connected. Therefore, for example, it is possible to arrange the fan 24 and the heat releasing module 23b on the upper side of the housing 3B regardless of the used position of the electronic device 1B. Accordingly, for example, heat is unlikely to remain in the housing 3B. The fan 24 and the heat releasing module 23b are arranged adjacent to the outlet 22b.

The board 7 is arranged on the other side of the cooling mechanism 23 with the board 6 interposed therebetween (in order of the board 7, the board 6, and the cooling mechanism 23 in the second portion 3Bb). Such a configuration causes the air inspired from the outside strikes the board 7 before reaching the position of the board 6. Therefore, for example, the heat release efficiency of the board 7 is improved. Furthermore, the board 7 on which the modules 8A and 8B are mounted is arranged on the other side of the cooling mechanism 23 serving as a heavy component with the board 6 interposed therebetween. The board 6 is a relatively heavy component among the components in the housing 3B, and is arranged in the center of the housing 3B. Therefore, for example, the balance of weight of the electronic device 1B can be improved. Accordingly, for example, the electronic device 1B is easier to carry for the user.

Furthermore, as illustrated in FIGS. 17 and 24, an inlet 22a2 closer to the fan 24, an inlet 22a3 arranged on the other side of the inlet 22a2 with the board 6 interposed therebetween, and the inlet 22a1 closer to the electronic component 12 serving as an heating element than the inlets 22a2 and 22a3 are provided to the wall 3m of the housing 3B in the present embodiment, for example. The arrangement of the inlet 22a2 allows the air to flow in the housing 3B more efficiently. Furthermore, air flow S introduced from the inlet 22a3 is divided into air flow S2 and air flow S1. The air flow S2 flows toward the fan 24 along a second surface 6b on the rear side of the board 6. By contrast, the air flow S1 passes through (flows around or make a detour around) the outside of an end 6c of the board 6 positioned on the other side of the fan 24, and that flows toward the fan 24 along a first surface 6a on the front side of the board 6. Therefore, it is possible to cool the electronic components (heating elements) 12 arranged on both sides of the first surface 6a and the second surface 6b of the board 6.

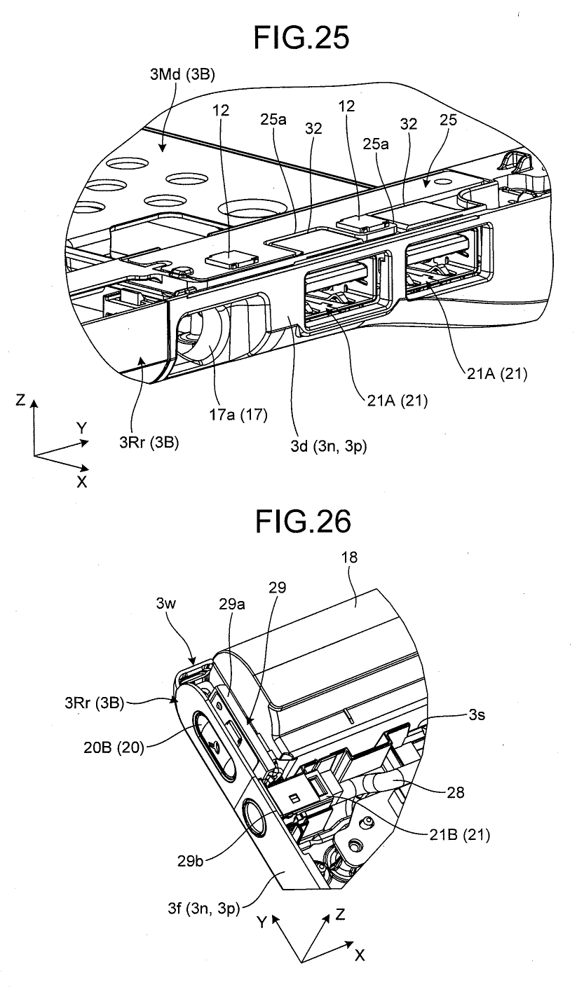

As illustrated in FIG. 25, connectors 21A (21) and the board 25 are arranged in a manner overlapped with each other in the width direction of the housing 3B in the present embodiment. The board 25 comprises the electronic components (e.g., a press switch) 12 that output a signal corresponding to an operation of a push button 20a of an operation module 20A. In the present embodiment, for example, the connector 21A or a recessed-protruding shape 32 formed by arranging the connector 21A can be used for positioning and supporting the board 25. The recessed-protruding shape is a recessed-protruding shape, a recessed portion or a protruding portion, or a projection provided to the third member 3Md in the present embodiment, for example. The board 25 comprises a recessed-protruding shape 25a (e.g., a projection, a notch, or a through hole; a notch in the present embodiment, for example) corresponding to the recessed-protruding shape 32. In the present embodiment, the recessed-protruding shape 32 provided to the third member 3Md is arranged in a manner corresponding to a movable area of a terminal (not illustrated) of the connector 21A. Thus, the recessed-protruding shape 32 functions as an escape portion that prevents the terminal from interfering with other components.

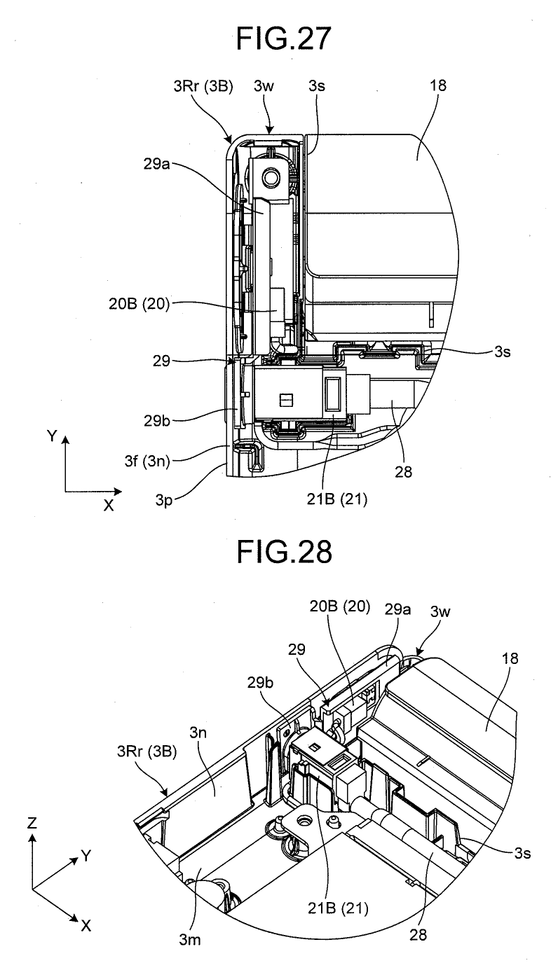

As illustrated in FIGS. 26 to 28, a bracket 29 for fixing and positioning an operation module 20B to the housing 3B is used for a bracket for fixing and positioning a connector 21B to the housing 3B in the present embodiment. In other words, for example, the bracket 29 comprises a first portion 29a that supports the operation module 20B and a second portion 29b that supports the connector 21B. The first portion 29a and the second portion 29b are configured in a plate shape along the wall 3n of the housing 3B. Such a configuration can reduce the number of components, for example. Furthermore, it is possible to reduce work and costs of manufacturing, for example.

With reference to FIG. 23 together with FIGS. 26 to 28, it is found that the operation modules 20 are arranged at positions on both sides of the battery 18 in the direction along the end 3c in the housing 3B in the present embodiment. In other words, in the present embodiment, the operation module 20 is provided to the inside of a supporting module 3w that supports an end of the battery 18 in the longitudinal direction. With such a configuration, for example, it is possible to use the dead space in this module more efficiently.

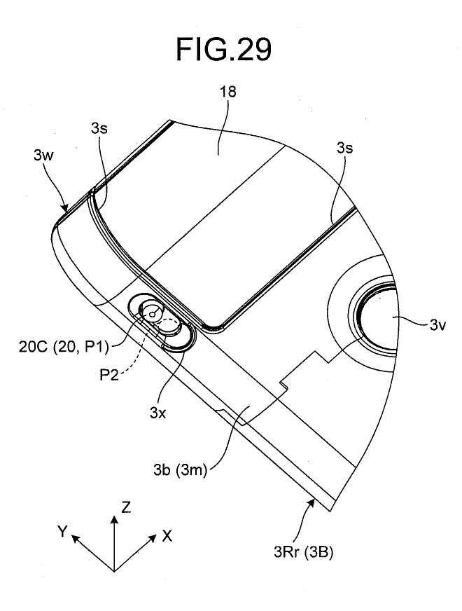

As illustrated in FIG. 29, a projection 3x that prevents an operation module 20C (20) serving as a slide switch from being operated erroneously in at least one direction is provided in the present embodiment. An operation element 20b of the operation module 20C is configured movably between a first position P1 and a second position P2. The operation element 20b is retained in at least the first position P1 and the second position P2 by a mechanism, which is not illustrated, in the operation module 20C, for example. However, it is not preferable that the operation element 20b be caused to move to the first position P1 or the second position P2 by an action of unintended external force. Therefore, the operation element 20b is recessed from the rear surface 3b of the housing 3B toward the inside thereof in the present embodiment. Furthermore, the projection 3x in a rib shape (a wall shape) serving as a barrier (an obstacle) that prevents a finger or an object from coming into contact with the operation element 20b is provided. The projection 3x is provided in a manner surrounding the projection 3x from the side opposite to the first position P1 with respect to the second position P2. The projection 3x is provided in a semicircle shape (an arc shape), for example. If the operation module 20C is a power switch for switching on and off of the power of the electronic device 1B, for example, it is preferable that the first position P1 be a position for power-off, and the second position P2 be a position for power-on. Therefore, it is possible to prevent some disadvantageous events from occurring because the operating element 20b is caused to move from the second position P2 to the first position P1 unintendedly to shut down the electronic device 1B.

While certain embodiments have been described, these embodiments have been presented by way of example only, and are not intended to limit the scope of the inventions. Indeed, the novel receiver and device described herein may be embodied in a variety of other forms. Furthermore, the technological characteristics in the embodiments can be combined appropriately. Moreover, specifications (a structure, a type, a direction, a shape, a size, a length, a width, a thickness, a height, the number, an arrangement, a position, a material, and the like) of each of the components can be changed appropriately. Furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

Moreover, the various modules of the systems described herein can be implemented as software applications, hardware and/or software modules, or components on one or more computers, such as servers. While the various modules are illustrated separately, they may share some or all of the same underlying logic or code.

What is claimed is:

1. A television receiver comprising:
a housing comprising an opening;
a display device in the housing comprising a display screen visible through the opening;
a first board in the housing comprising a heating element mounted thereon;
a second board in the housing at a position different from that of the first board, different in size from that of the first board, configured to be electrically connected to the first board, and comprising a first surface and a second surface, the first surface on the display device side and the second surface on a side opposite the first surface, the first surface comprising a first connector, a first fixing portion, and a first planer portion between the first connector and the first fixing portion with no surface mount component mounted thereon, the second surface comprising a second connector, a second fixing portion, and a second planer portion between the second connector and the second fixing portion with no surface mount component mounted thereon;
a first card module configured to be electrically connected to the first connector, and on the first planer portion and along the first surface; and
a second card module on the second planer portion and along the second surface at a position at least partially overlapping the first card module in a thickness direction of the second board, electrically connected to the second connector, and configured to have a higher operation temperature than the first card module.

2. The television receiver of claim 1, wherein an electronic component is provided to at least one of a first area on the first surface at a back side of the second card module and a second area on the second surface on a rear side of the first card module.

3. The television receiver of claim 2, wherein the electronic component is a temperature sensor on the first area.

4. The television receiver of claim 1, wherein a through hole to the second board is shared by the first connector and the second connector fixed to the second board.

5. The television receiver of claim 1, wherein a through hole to the second board is shared by the first fixing portion and the second fixing portion fixed to the second board.

6. The television receiver of claim 1, wherein a size of the first card module viewed in a thickness direction of the second board is the same as a size of the second card module viewed in the thickness direction of the second board.

7. The television receiver of claim 6, wherein:
a longitudinal direction of the first card module is parallel to a longitudinal direction of the second card module, and
the first card module and the second card module are misaligned in the longitudinal direction of the first card module or the longitudinal direction of the second card module.

8. The television receiver of claim 6, wherein the first card module and the second card module are configured to completely overlap each other in the thickness direction of the second board.

9. The television receiver of claim 1, comprising a flexible cable configured to electrically connect the first board and the second board with each other, and to be attachable to and detachable from at least one of the first board and the second board.

10. The television receiver of claim 1, wherein an index for mounting is provided to at least one of the first card module and the second card module.

11. An electronic device comprising:
a housing;
a first board in the housing;
a second board in the housing configured to be electrically connected to the first board and comprising a first surface and a second surface on a side opposite the first surface;
a first portion on the first surface; and
a second portion on the second surface and configured to at least partially overlap the first portion in a thickness direction of the second board.
